(19) United States
(12) Patent Application Publication
(10) Pub. No.: US 2024/0417518 A1
(43) Pub. Date: Dec. 19, 2024

(54) THERMOMETRIC HYDROGEL COMPOSITIONS, FLEXIBLE THERMAL SENSORS COMPRISING THE SAME AND METHODS OF MAKING THEREOF

(71) Applicant: Hong Kong Centre for Logistics Robotics Limited, Hong Kong (CN)

(72) Inventors: DONGYAN XU, Hong Kong (CN); HAOXIANG WEI, Hong Kong (CN); YANG HAN, Hong Kong (CN); YANJUN DU, Hong Kong (CN)

(21) Appl. No.: 18/336,009

(22) Filed: Jun. 15, 2023

(51) Int. Cl. C08J 3/075; C08K 3/22; C08L 79/02; H05K 1/03

(52) U.S. Cl. CPC C08J 3/075; C08K 3/22; C08L 79/02; H05K 1/0373; C08J 2379/02; C08L 2203/206

(57) ABSTRACT

In some embodiments, provided is a thermometric hydrogel composition for thermal sensor and methods of making thereof, wherein the composition including at least one polyquaternium (PQ), at least one ion source and a solvent. In other aspect, provided is a device comprising the thermometric hydrogel composition and methods of making thereof. Other example embodiments are described herein. In certain embodiments, the flexible thermal sensor comprising such thermometric hydrogel composition has high flexibility, high thermal sensitivity and low fabrication cost.

### FIELD OF INVENTION

This application relates to thermometric compositions, devices comprising the same and methods of making thereof. More specifically, the present invention relates to thermometric hydrogel compositions, flexible thermal sensors comprising the same and methods of making such compositions and sensors.

### BACKGROUND OF INVENTION

Temperature sensing plays a critical role in industry and our daily life. Thermal sensors are key components for a variety of applications, including process control, healthcare, biomedical sensing, environmental monitoring, etc. Commonly used temperature sensors include mercury thermometers, thermistors, resistance thermometers, thermocouples, infrared thermometers, etc., which convert temperature information into measurable signals through thermometric materials.

Conventional temperature sensors, such as thermocouples and resistance thermometers, are typically made of rigid electronic materials, i.e., metals and semiconductors. With the emergence of flexible electronics, sensors with good flexibility, high sensitivity, and low fabrication cost are highly desirable.

Similar to the commonly used electronic conductors, such as metals and semiconductors, ionic conductors can perceive thermal signal through the potential difference induced by an internal temperature gradient, whereas charge carriers are ions rather than electrons. The sensitivity of ionic conductors can be described by thermopower (mV/K), which represents the generated potential difference per unit temperature difference.

The wide application of liquid-state ionic materials is hindered by the potential leakage issue, which requires careful and complicated encapsulating process. As comparison, solid-state ionic conductors show the advantage of better stability, which can be used as thermal sensors without complicated packaging. However, the solid-state ionic conductors usually have poor contact with electrodes, which poses a great challenge for sensor fabrication. Therefore, improved thermometric compositions and flexible sensors comprising the same with good flexibility, high sensitivity, and low fabrication cost are highly desirable.

### SUMMARY OF INVENTION

In light of the foregoing background, in certain embodiments, there is a need for new class of thermometric materials such as thermometric ionic hydrogels as featuring high flexibility, high thermal sensitivity and low fabrication cost. Moreover, there is a need for improved flexible temperature or thermal sensors (or arrays) and fabrication methods thereof, which can be easily patterned and manufactured at low cost, based on the new class of the thermometric materials.

Accordingly, in some embodiments, provided is a thermometric hydrogel composition for thermal sensor, including: (a) at least one polyquaternium (PQ) having at least one quaternary ammonium group; (b) at least one ion source; and (c) a solvent. In some embodiments, the thermometric hydrogel composition consists of or essentially consists of (a) polyquaternium (PQ); (b) at least one ion source; and (c) water. In some embodiments, the thermometric hydrogel composition consists of or essentially consists of (a) polyquaternium (PQ); (b) at least one ion source; and (c) a solvent. In some embodiments, provided is a thermometric hydrogel composition for thermal sensor, including: (a) polyquaternium-10 (PQ-10); (b) at least one ion source; and (c) water. In some embodiments, the thermometric hydrogel composition consists of or essentially consists of (a) polyquaternium-10 (PQ-10); (b) at least one ion source; and (c) water. In some embodiments, the thermometric hydrogel composition consists of or essentially consists of (a) polyquaternium-10 (PQ-10); (b) at least one ion source, and (c) a solvent. In some embodiments, the hydrogel composition forms a hydrogel exhibiting a thermopower of at least about 7.79 or 24.17 mV/K. In some embodiments, the thermopower is at least about 7, 10, 15, 20, 25, 30, 35, 40, 45, 50 or more mV/K.

In some embodiments, the at least one ion source includes one or more acids, alkalis, salts, ionic liquids, and/or combination thereof. Example acids include, but are not limited to, hydrochloric acid (HCl), sulfuric acid (H₂SO₄), nitric acid (HNO₃), and phosphoric acid (H₃PO₄). Example alkalis include, but are not limited to, sodium hydroxide (NaOH) and potassium hydroxide (KOH). Example salts include, but are not limited to, sodium chloride (NaCl), lithium sulfate (Li₂SO₄), potassium chloride (KCl), and potassium nitrate (KNO₃). Example ionic liquids include, but are not limited to, 1-ethyl-3-methylimidazolium chloride ([EMIM]Cl), 1-ethyl-3-methylimidazolium bis(trifluoromethylsulfonyl)imide ([EMIM]TFSI), 1-ethyl-3-methylimidazolium dicyanamide ([EMIM]DCA), and 1-butyl-3-methylimidazolium tetrafluoroborate ([BMIM]BF4).

In some embodiments, provided is a composition, wherein the solvent is water, ionic liquids, ethanol, ethylene glycol, dimethyl sulfoxide, or combination thereof.

In some embodiments, the composition is dried to a water content of about 14-55 wt. % to form a PQ based ionic hydrogel, wherein final PQ and ion source contents are in the ranges of 15-72 wt. % and 7-58 wt. %, respectively. In some embodiments, the water content is about 14, 14.5, 15, 15.5, 16, 16.5, 17, 17.5, 18, 18.5, 19, 19.5, 20, 20.5, 21, 21.5, 22, 22.5, 23, 23.5, 24, 24.5, 25, 25.5, 26, 26.5, 27, 27.5, 28, 28.5, 29, 29.5, 30, 30.5, 31, 31.5, 32, 32.5, 33, 33.5, 34, 34.5, 35, 35.5, 36, 36.5, 37, 37.5, 38, 38.5, 39, 39.5, 40, 40.5, 41, 41.5, 42, 42.5, 43, 43.5, 44, 44.5, 45, 45.5, 46, 46.5, 47, 47.5, 48, 48.5, 49, 49.5, 50, 50.5, 51, 51.5, 52, 52.5, 53, 53.5, 54, 54.5, or 55 wt. %. In some embodiments, the final PQ content is about 15, 15.5, 16, 16.5, 17, 17.5, 18, 18.5, 19, 19.5, 20, 20.5, 21, 21.5, 22, 22.5, 23, 23.5, 24, 24.5, 25, 25.5, 26, 26.5, 27, 27.5, 28, 28.5, 29, 29.5, 30, 30.5, 31, 31.5, 32, 32.5, 33, 33.5, 34, 34.5, 35, 35.5, 36, 36.5, 37, 37.5, 38, 38.5, 39, 39.5, 40, 40.5, 41, 41.5, 42, 42.5, 43, 43.5, 44, 44.5, 45, 45.5, 46, 46.5, 47, 47.5, 48, 48.5, 49, 49.5, 50, 50.5, 51, 51.5, 52, 52.5, 53, 53.5, 54, 54.5, 55, 55.5, 56, 56.5, 57, 57.5, 58, 58.5, 59, 59.5, 60, 60.5, 61, 61.5, 62, 62.5, 63, 63.5, 64, 64.5, 65, 65.5, 66, 66.5, 67, 67.5, 68, 68.5, 69, 69.5, 70, 70.5, 71, 71.5, or 72 wt. %. In some embodiments, the final ion source content is about 7, 7.5, 8, 8.5, 9, 9.5, 10, 10.5, 11, 11.5, 12, 12.5, 13, 13.5, 14, 14.5, 15, 15.5, 16, 16.5, 17, 17.5, 18, 18.5, 19, 19.5, 20, 20.5, 21, 21.5, 22, 22.5, 23, 23.5, 24, 24.5, 25, 25.5, 26, 26.5, 27, 27.5, 28, 28.5, 29, 29.5, 30, 30.5, 31, 31.5, 32, 32.5, 33, 33.5, 34, 34.5, 35, 35.5, 36, 36.5, 37, 37.5, 38, 38.5, 39, 39.5, 40, 40.5, 41, 41.5, 42, 42.5, 43, 43.5, 44, 44.5, 45, 45.5, 46, 46.5, 47, 47.5, 48, 48.5, 49, 49.5, 50, 50.5, 51, 51.5, 52, 52.5, 53, 53.5, 54, 54.5, 55, 55.5, 56, 56.5, 57, 57.5, or 58 wt. %.

In some embodiments, the at least one ion source is sodium hydroxide (NaOH) and the weight ratio of PQ:NaOH is about 5:1 to 5:8. In some embodiments, the weight ratio of PQ:NaOH is about 5:1, 5:2, 5:3, 5:4, 5:5, 5:6, 5:7 or 5:8.

In some embodiments, the PQ is polyquaternium-10 (PQ-10) which is about 3-4% by weight; and the NaOH is about 0.6-4.9% by weight of the composition, wherein the composition has a pH value of about 13-14. In some embodiments, the PQ-10 is about 3, 3.5 or 4% by weight of the composition.

In some embodiments, the NaOH is about 0.1, 0.2, 0.3, 0.4, 0.5, 0.6, 0.7, 0.8, 0.9, 1, 1.5, 2, 2.5, 3, 3.5, 4, 4.5, or 5% by weight of the composition. In some embodiments, the composition has a pH value of about 13, 13.5 or 14.

In some embodiments, the at least one ion source is 1-ethyl-3-methylimidazolium chloride ([EMIM]Cl) and the weight ratio of PQ:[EMIM]Cl is about 1:0.5 to 1:2. In some embodiments, the weight ratio of PQ:[EMIM]Cl is about 1:0.5, 1:1, 1:1.5, or 1:2.

In some embodiments, the PQ is PQ-10 which is about 7.7-8.7% by weight; and the [EMIM]Cl is about 4.3-15.4% by weight of the composition, wherein the composition has a pH value of about 4-11. In some embodiments, the PQ-10 is about 7.5, 8, 8.5 or 9% by weight. In some embodiments, the [EMIM]Cl is about 4, 4.5, 5, 5.5, 6, 6.5, 7, 7.5, 8, 8.5, 9, 9.5, 10, 10.5, 11, 11.5, 12, 12.5, 13, 13.5, 14, 14.5, 15, 15.5, 16, 16.5, 17, 17.5, 18, 18.5, 19, 19.5, or 20% by weight of the composition. In some embodiments, the pH value of the composition is about 4, 4.5, 5, 5.5, 6, 6.5, 7, 7.5, 8, 8.5, 9, 9.5, 10, 10.5, or 11.

In some embodiments, provided is a method of preparing a thermometric hydrogel composition for thermal sensor, including the step of: (a) mixing at least one polyquaternium, such as polyquaternium-10 (PQ-10), into a solution including at least one ion source to form a mixture; (b) adjusting the pH value of the mixture to form a composition; (c) drying the composition to a gel state, such that a PQ based ionic hydrogel is formed.

In some embodiments, the at least one ion source includes one or more acids, alkalis, salts, ionic liquids, and/or combination thereof.

In some embodiments, the at least one ion source is NaOH and the weight ratio of PQ:NaOH is about 5:1 to 5:8. In some embodiments, the weight ratio of PQ:NaOH is about 5:1, 5:2, 5:3, 5:4, 5:5, 5:6, 5:7 or 5:8.

In some embodiments, the composition includes: the PQ is polyquaternium-10 (PQ-10) of about 3-4% by weight; and the NaOH of about 0.6-4.9% by weight of the composition, wherein the pH value is adjusted to about 13-14. In some embodiments, the PQ-10 is about 3, 3.5 or 4% by weight. In some embodiments, the NaOH is about 0.6, 0.8, 1.0, 1.5, 2.0, 2.5, 3.0, 3.5, 4.0, 4.5, or 5.0% by weight of the composition. In some embodiments, the composition has a pH value of about 13, 13.5 or 14.

In some embodiments, the step c) drying the composition to a gel state is performed at about 40° C. for 20-50 hours, until the water content is about in the range of 14-55 wt. %. In some embodiments, the step c) drying the composition to a gel state is performed at about 20, 30, 40, 50 or 60° C. In some embodiments, the duration is about 20, 30, 40 or 50 hours. In some embodiments, the water content is about 14, 15, 20, 25, 30, 35, 40, 45, 50, or 55 wt. %.

In some embodiments, the at least one ion source is [EMIM]Cl and the weight ratio of PQ:[EMIM]Cl is about 1:0.5 to 1:2. In some embodiments, the weight ratio of PQ:[EMIM]Cl is about 1:0.5, 1:1, 1:1.5, or 1:2.

In some embodiments, the composition includes: the PQ is PQ-10 of about 7.7-8.7% by weight; and the [EMIM]Cl of about 4.3-15.4% by weight of the composition, wherein the pH value is adjusted to about 4-11. In some embodiments, the PQ-10 is about 7.5, 8, 8.5, or 9% by weight. In some embodiments, the [EMIM]Cl is about 4, 5, 10, 15, or 20% by weight of the composition. In some embodiments, the pH value of the composition is about 4, 4.5, 5, 5.5, 6, 6.5, 7, 7.5, 8, 8.5, 9, 9.5, 10, 10.5, or 11.

In some embodiments, provided is a flexible thermal sensor, including: (a) a flexible substrate; (b) a first flexible printed circuit board (FPCB) that is disposed on the flexible substrate, the first FPCB including: (i) a plurality of first electrodes; and (ii) a plurality of first connecting lines, wherein individual first electrode is in electrical communication with individual first connecting line; (c) a mask layer that is disposed on the first FPCB; (d) at least one PQ based ionic hydrogel; and (e) an insulating layer that is disposed onto the first FPCB, wherein the mask layer includes at least one receiving portion, defining at least one space that is sized and shaped large enough to receive at least a portion of the first electrodes and at least one remaining space to receive the at least one PQ based ionic hydrogel, such that at least a portion of the first electrodes is in electrical communication with the at least one PQ based ionic hydrogel.

In some embodiments, the mask layer includes one receiving portion, defining one space sized and shaped large enough to receive the plurality of first electrodes, and the remaining space is sized and shaped large enough to receive one PQ based ionic hydrogel to at least cover the plurality of first electrodes, such that the plurality of first electrodes are in electrical communication with each other through the PQ based ionic hydrogel.

In some embodiments, the flexible thermal sensor further includes a second flexible printed circuit board (FPCB), the second FPCB including: a plurality of second electrodes; and a plurality of second connecting lines, wherein individual second electrode is in electrical communication with individual second connecting line, wherein each of the plurality of second electrodes is positioned juxtapose to the corresponding first electrode, wherein the second FPCB is disposed on the first FPCB and below the insulating layer, and wherein the mask layer includes a plurality of receiving portions, defining a plurality of spaces, individual space is sized and shaped large enough to receive individual first electrode and individual second electrode, and the remaining space between the first electrode and the second electrode is sized and shaped large enough to receive PQ based ionic hydrogel therebetween, such that the first electrode is in electrical communication with the second electrode through the PQ based ionic hydrogel.

In some embodiments, at least one electrode is a sensing electrode and at least another one electrode is a reference electrode.

In some embodiments, the PQ based ionic hydrogel includes a thermometric hydrogel composition described above.

In some embodiments, the PQ based ionic hydrogel is prepared by the method of preparing a thermometric hydrogel composition for thermal sensor described above.

In some embodiments, provided is a method of making a flexible thermal sensor, including: (a) providing a first flexible printed circuit board (FPCB) onto a flexible substrate, wherein the first FPCB includes a plurality of first electrodes and a plurality of first connecting lines, wherein individual first electrode is in electrical communication with individual first connecting line; (b) attaching at least one mask layer onto the first FPCB, wherein the mask layer includes at least one receiving portion, defining at least one space that is sized and shaped large enough to receive at least a portion of the first electrodes and at least one remaining space to receive at least one PQ based ionic hydrogel; (c) casting a thermometric hydrogel composition including at least one dissolved PQ and at least one ion source onto the at least one remaining space; (d) drying the composition to a gel state to form the at least one PQ based ionic hydrogel, such that at least a portion of the first electrodes is in electrical communication with the at least one PQ based ionic hydrogel; (e) attaching an insulating layer onto the first FPCB.

In some embodiments, the method further includes a step of attaching a second flexible printed circuit board (FPCB) onto the first FPCB and below the insulating layer, prior to step (c), wherein the second FPCB includes a plurality of second electrodes and a plurality of second connecting lines, wherein individual second electrode is in electrical communication with individual second connecting line, wherein each of the plurality of second electrodes is positioned juxtapose to the corresponding first electrode, and wherein the mask layer includes a plurality of receiving portions, defining a plurality of spaces, individual space is sized and shaped large enough to receive individual first electrode and individual second electrode, and the remaining space between the first electrode and the second electrode is sized and shaped large enough to receive PQ based ionic hydrogel therebetween, such that the first electrode is in electrical communication with the second electrode through the PQ based ionic hydrogel.

In some embodiments, at least one electrode is a sensing electrode and at least another one electrode is a reference electrode.

In some embodiments, the PQ based ionic hydrogel includes a thermometric hydrogel composition described above.

In some embodiments, the PQ based ionic hydrogel is prepared by the method of preparing a thermometric hydrogel composition for thermal sensor described above.

In certain embodiments, provided is a new class of ionic hydrogels as temperature sensing materials and the fabrication methods of flexible thermal sensors (arrays) based on the developed ionic hydrogels. The ionic hydrogels comprise at least one polyquaternium, such as polyquaternium-1 (PQ-1), polyquaternium-7 (PQ-7), polyquaternium-10 (PQ-10), polyquaternium-22 (PQ-22), as a polymer matrix and one or more alternative ion sources including but not limited to acids, alkalis, salts, and ionic liquids. Under a thermal gradient, cations in the hydrogel diffuse freely from the hot side to the cold side, while the diffusion of anions is impeded by electrostatic interaction with the positively charged quaternary ammonium groups of polyquaternium such as PQ-10. The unbalanced distribution of anions and cations gives rise to a potential difference between the hot and cold sides, and thus converts the temperature information to an electrical signal.

Other example embodiments will be described below.

In certain embodiments, a new class of ionic hydrogels as thermometric hydrogel compositions (or temperature sensing materials) and methods of preparing the same, the flexible thermal sensors comprising such compositions, and the method of making the same (or the fabrication methods of flexible temperature sensors (arrays)) are provided.

In certain embodiments, the temperature sensing material comprises or consists of at least one polyquaternium as the polymer matrix and further comprises one or more alternative ion sources.

In certain embodiments, the temperature sensing material comprises or consists of PQ-10 as the polymer matrix and further comprises one or more alternative ion sources. In certain embodiments, the ionic hydrogels are prepared by mixing polyquaternium such as PQ-10 powders with the solution of ion sources, tuning the pH value of the mixture, and drying the obtained solution in a container to gel state under controlled conditions.

Without bound by any theory, in certain embodiments, the positively charged quaternary amine groups in polyquaternium (PQ) such as PQ-10 can immobilize anions through strong electrostatic interaction, leading to higher mobility of cations and thus a thermal voltage under a temperature gradient.

In certain embodiments, the gel-like temperature sensing materials are prepared by dissolving PQ and one or more ion sources in deionized water, drop casting the solution into a container, and then drying to gel state under controlled conditions. The thermopower and sensitivity of the temperature sensing materials can be adjusted through tuning the water content, the pH value, and the weight ratio of PQ to ion sources. In certain embodiments, an in-plane flexible temperature sensor array is fabricated through patterning the sensing materials onto a FPCB with the designed sensing and reference electrodes, followed by drying and packaging. In some other embodiments, the flexible temperature sensor (array) with the cross-plane configuration can be fabricated through similar methods.

There are many advantages of the present disclosure. In certain embodiments, the ionic hydrogel formed by the thermometric hydrogel composition has the properties of high thermopower, outstanding formability, ease of patterning, and good contact with electrodes. In certain embodiments, the ionic hydrogel formed by the provided thermometric hydrogel composition has the properties of disposability, biocompatibility, and stretchability.

In certain embodiments, the thermal sensor comprising such ionic hydrogels has high flexibility, high thermal sensitivity and low fabrication cost.

The fabricated flexible temperature sensor array shows the desired capability to detect spatial temperature signals with high sensitivity, providing a promising solution for temperature sensing on soft or deformable surfaces.

### BRIEF DESCRIPTION OF FIGURES

FIG. 1A is a flowchart of an example method of preparing a thermometric hydrogel composition for a thermal sensor.

FIG. 1B is a schematic setup to characterize the thermopower of an example ionic hydrogel.

FIG. 2A shows the measured ΔV in response to a thermal stimulus of ΔT of an example PQ based ionic hydrogel with PQ-10:NaOH=5:2.

FIG. 2B shows ΔV vs. ΔT extracted from FIG. 2A and the thermopower determined from the slope of the linear fitting thereof.

FIG. 3A is a photograph of an example PQ-10/[EMIM]Cl ionic hydrogel before being stretched.

FIG. 3B is a photograph of an example PQ-10/[EMIM]Cl ionic hydrogel after being stretched.

FIG. 4 is a flowchart of an example method of preparing a flexible thermal sensor.

FIG. 5A is an exploded view of an example in-plane flexible thermal sensor.

FIG. 5B is a top view of an example flexible thermal sensor.

FIG. 5C is a schematic diagram illustrating an example method of preparing the example flexible thermal sensor, according to FIG. 5A.

FIG. 5D is a photograph of an example flexible thermal sensor.

FIG. 5E illustrates the finger touch-release test of an example flexible thermal sensor with sequential finger touch from electrodes (or sensor nodes) A to E.

FIG. 5F shows the ΔVₛ₋ᵣ and temperature recorded in a cyclic finger touch-release test at one of the sensor nodes of the example flexible thermal sensor.

FIG. 5G shows the ΔVₛ₋ᵣ recorded for five sensor nodes of the example flexible thermal sensor in a sequential finger touch-release test, according to FIG. 5E.

FIG. 6A is a cross-sectional view of another example cross-plane flexible thermal sensor.

FIGS. 6B-6C are schematic diagrams illustrating an example method of preparing the example flexible thermal sensor, according to FIG. 6A.

### DETAILED DESCRIPTION

As used herein and in the claims, the terms “comprising” (or any related form such as “comprise” and “comprises”), “including” (or any related forms such as “include” or “includes”), “containing” (or any related forms such as “contain” or “contains”), means including the following elements but not excluding others. It shall be understood that for every embodiment in which the term “comprising” (or any related form such as “comprise” and “comprises”), “including” (or any related forms such as “include” or “includes”), or “containing” (or any related forms such as “contain” or “contains”) is used, this disclosure/application also includes alternate embodiments where the term “comprising”, “including.” or “containing,” is replaced with “consisting essentially of” or “consisting of”. These alternate embodiments that use “consisting of” or “consisting essentially of” are understood to be narrower embodiments of the “comprising”, “including.” or “containing,” embodiments.

For the sake of clarity, “comprising”, “including”, “containing” and “having”, and any related forms are open-ended terms which allows for additional elements or features beyond the named essential elements, whereas “consisting of” is a closed end term that is limited to the elements recited in the claim and excludes any element, step, or ingredient not specified in the claim.

For the sake of clarity, “characterized by” or “characterized in” (together with their related forms as described above), does not limit or change the nature of whether the list of terms following it are open or closed. For example, in a claim directed towards “a device comprising A, B, C, and characterized by D, E, and F”, the elements D, E, and F are still open-ended terms and the claim is meant to include other elements due to the use of the word “comprising” earlier in the claim.

“Consisting essentially of” limits the scope of a claim to the specified materials, components, or steps (“essential elements”) that do not materially affect the essential characteristic(s) of the claimed invention. In some embodiments, the essential characteristics are the basic and novel characteristic(s) of the claimed invention.

As used herein, the singular forms “a”, “an” and “the” are intended to include the plural forms as well, unless the context clearly indicates otherwise. Where a range is referred in the specification, the range is understood to include each discrete point within the range. For example, 1-7 means 1, 2, 3, 4, 5, 6, and 7.

As used herein, the term “about” is understood as within a range of normal tolerance in the art and not more than ±10% of a stated value. By way of example only, about 50 means from 45 to 55 including all values in between. As used herein, the phrase “about” a specific value also includes the specific value, for example, about 50 includes 50.

As used herein and in the claims, the terms “general” or “generally”, or “substantial” or “substantially” mean that the recited characteristic, angle, shape, state, structure, or value need not be achieved exactly, but that deviations or variations, including for example, tolerances, measurement error, measurement accuracy limitations and other factors known to those of skill in the art, may occur in amounts that do not preclude the effect the characteristic was intended to provide. For example, an object that has a “generally” cylindrical shape would mean that the object has either an exact cylindrical shape or a nearly exact cylindrical shape. In another example, an object that is “substantially” perpendicular to a surface would mean that the object is either exactly perpendicular to the surface or nearly exactly perpendicular to the surface, e.g., has a 5% deviation.

It is to be understood that terms such as “top”, “bottom”, “middle”, “side”, “length”, “inner”, “outer”, “interior”, “exterior”, “outside”, “vertical”, “horizontal” and the like as may be used herein, merely describe points of reference and do not limit the present invention to any particular orientation or configuration. Further, terms such as “first,” “second,” “third,” etc., merely identify one of a number of portions, components and/or points of reference as disclosed herein, and likewise do not limit the present invention to any particular configuration or orientation.

As used herein, the terms “polyquaternium” or “PQ” refer to a polymeric substance comprising at least one quaternary ammonium group. In some embodiments, polyquaternium or PQ refers to a polymeric quaternary ammonium salt of hydroxyethyl cellulose. In some embodiments, the polyquaternium or PQ is polyquaternium-1, polyquaternium-7, polyquaternium-10, polyquaternium-22, or combination thereof. In some embodiments, polyquaternium or PQ is polyquaternium-10. In some embodiments, polyquaternium or PQ refers to a substance identified by the CAS no. 53568-66-4, 54351-50-7, 55353-19-0, 68610-92-4, or 81859-24-7.

As used herein, the term “hydrogel” means a biphasic material made of a mixture of porous, permeable solids such as polymers and a fluid or solvent such as water, ionic liquids, ethanol, ethylene glycol, dimethyl sulfoxide, or combination thereof. In some embodiments, the hydrogel is a gel-like material made from a hydrogel composition that contains at least one polyquaternium as the polymer.

As used herein, the term “solvent” refers to a substance which is capable of dissolving or dispersing other substances. Examples of a solvent include, but are not limited to, water, ionic liquids, ethanol, ethylene glycol, dimethyl sulfoxide, and combination thereof.

As used herein, the terms “thermal sensor” or “temperature sensor” refer to a device that exhibits a signal when subjected to a corresponding temperature change. In some embodiments, a thermal sensor or temperature sensor exhibits a signal of electrical potential difference in response to a temperature gradient.

As used herein, the terms “sensor array” refers to a group of sensors deployed in a certain geometry pattern. In some embodiments, at least one sensor can form at least a part of a thermal sensor array or a temperature sensor array.

As used herein, the term “ion source” refers to one or more compounds comprising at least one cation and one anion to form an ionic hydrogel, within a polymer matrix.

As used herein, the terms “disposed on”, “disposed onto” are used when describing an element being positioned on another element either directly or indirectly. In some embodiments, indirectly disposed on or disposed onto means that there are one or more additional elements between the two elements.

As used herein, the terms “attach”, “attaching”, or “attached to” refers to physical connection to another element, either directly or indirectly. In some embodiments, indirectly “attach”, “attaching”, or “attached to” means that there are one or more additional elements attached between the two elements.

The term “electrode” refers to a conducting conductor that is capable of transferring charged particles (such as electrons, cations or anions) and communicating to another one or more elements by electrical means, electrochemical means, ionic means, or combination thereof. In some embodiments, an electrode is a sensor node or sensing electrode. In some embodiments, an electrode is a reference electrode. In some embodiments, an electrode is an auxiliary electrode. When one or more electrodes are electrically connected by ionic hydrogel, they can form in-plane or cross-plane sensor array together.

The term “electrical communication” refers to the communication between two or more elements where charged particles (such as electrons, cations or anions) generated by electrical means, electrochemical means, ionic means, or combination thereof, are transferred or transmitted from one element to another. For example, when a plurality of electrodes is in direct contact with the PQ based ionic hydrogel, the plurality of electrodes and the PQ based ionic hydrogel are in electrical communication with each other. For example, when a potential difference is generated in the PQ based ionic hydrogel due to the unbalanced diffusion of cations and anions under a temperature gradient, the electrical signal generated from the said potential difference is transmitted to the external circuit connected to the electrodes via the electrical communication among the plurality of electrodes and the PQ based ionic hydrogel.

In some embodiments, the water content is about 0.1, 0.2, 0.3, 0.4, 0.5, 0.6, 0.7, 0.8, 0.9, 1, 1.5, 2, 2.5, 3, 3.5, 4, 4.5, 5, 5.5, 6, 6.5, 7, 7.5, 8, 8.5, 9, 9.5, 10, 10.5, 11, 11.5, 12, 12.5, 13, 13.5, 14, 14.5, 15, 15.5, 16, 16.5, 17, 17.5, 18, 18.5, 19, 19.5, 20, 20.5, 21, 21.5, 22, 22.5, 23, 23.5, 24, 24.5, 25, 25.5, 26, 26.5, 27, 27.5, 28, 28.5, 29, 29.5, 30, 30.5, 31, 31.5, 32, 32.5, 33, 33.5, 34, 34.5, 35, 35.5, 36, 36.5, 37, 37.5, 38, 38.5, 39, 39.5, 40, 40.5, 41, 41.5, 42, 42.5, 43, 43.5, 44, 44.5, 45, 45.5, 46, 46.5, 47, 47.5, 48, 48.5, 49, 49.5, 50, 50.5, 51, 51.5, 52, 52.5, 53, 53.5, 54, 54.5, 55, 55.5, 56, 56.5, 57, 57.5, 58, 58.5, 59, 59.5, 60, 60.5, 61, 61.5, 62, 62.5, 63, 63.5, 64, 64.5, 65, 65.5, 66, 66.5, 67, 67.5, 68, 68.5, 69, 69.5, 70, 70.5, 71, 71.5, 72, 72.5, 73, 73.5, 74, 74.5, 75, 75.5, 76, 76.5, 77, 77.5, 78, 78.5, 79, 79.5, 80, 80.5, 81, 81.5, 82, 82.5, 83, 83.5, 84, 84.5, 85, 85.5, 86, 86.5, 87, 87.5, 88, 88.5, 89, 89.5, 90, 90.5, 91, 91.5, 92, 92.5, 93, 93.5, 94, 94.5, 95, 95.5, 96, 96.5, 97, 97.5, 98, 98.5, 99, 99.5, or 100 wt. %.

In some embodiments, the PQ is about 0.1, 0.2, 0.3, 0.4, 0.5, 0.6, 0.7, 0.8, 0.9, 1, 1.5, 2, 2.5, 3, 3.5, 4, 4.5, 5, 5.5, 6, 6.5, 7, 7.5, 8, 8.5, 9, 9.5, 10, 10.5, 11, 11.5, 12, 12.5, 13, 13.5, 14, 14.5, 15, 15.5, 16, 16.5, 17, 17.5, 18, 18.5, 19, 19.5, 20, 20.5, 21, 21.5, 22, 22.5, 23, 23.5, 24, 24.5, 25, 25.5, 26, 26.5, 27, 27.5, 28, 28.5, 29, 29.5, 30, 30.5, 31, 31.5, 32, 32.5, 33, 33.5, 34, 34.5, 35, 35.5, 36, 36.5, 37, 37.5, 38, 38.5, 39, 39.5, 40, 40.5, 41, 41.5, 42, 42.5, 43, 43.5, 44, 44.5, 45, 45.5, 46, 46.5, 47, 47.5, 48, 48.5, 49, 49.5, 50, 50.5, 51, 51.5, 52, 52.5, 53, 53.5, 54, 54.5, 55, 55.5, 56, 56.5, 57, 57.5, 58, 58.5, 59, 59.5, 60, 60.5, 61, 61.5, 62, 62.5, 63, 63.5, 64, 64.5, 65, 65.5, 66, 66.5, 67, 67.5, 68, 68.5, 69, 69.5, 70, 70.5, 71, 71.5, 72, 72.5, 73, 73.5, 74, 74.5, 75, 75.5, 76, 76.5, 77, 77.5, 78, 78.5, 79, 79.5, 80, 80.5, 81, 81.5, 82, 82.5, 83, 83.5, 84, 84.5, 85, 85.5, 86, 86.5, 87, 87.5, 88, 88.5, 89, 89.5, 90, 90.5, 91, 91.5, 92, 92.5, 93, 93.5, 94, 94.5, 95, 95.5, 96, 96.5, 97, 97.5, 98, 98.5, 99, 99.5, or 100% by weight of the composition.

In some embodiments, the ion source is about 0.1, 0.2, 0.3, 0.4, 0.5, 0.6, 0.7, 0.8, 0.9, 1, 1.5, 2, 2.5, 3, 3.5, 4, 4.5, 5, 5.5, 6, 6.5, 7, 7.5, 8, 8.5, 9, 9.5, 10, 10.5, 11, 11.5, 12, 12.5, 13, 13.5, 14, 14.5, 15, 15.5, 16, 16.5, 17, 17.5, 18, 18.5, 19, 19.5, 20, 20.5, 21, 21.5, 22, 22.5, 23, 23.5, 24, 24.5, 25, 25.5, 26, 26.5, 27, 27.5, 28, 28.5, 29, 29.5, 30, 30.5, 31, 31.5, 32, 32.5, 33, 33.5, 34, 34.5, 35, 35.5, 36, 36.5, 37, 37.5, 38, 38.5, 39, 39.5, 40, 40.5, 41, 41.5, 42, 42.5, 43, 43.5, 44, 44.5, 45, 45.5, 46, 46.5, 47, 47.5, 48, 48.5, 49, 49.5, 50, 50.5, 51, 51.5, 52, 52.5, 53, 53.5, 54, 54.5, 55, 55.5, 56, 56.5, 57, 57.5, 58, 58.5, 59, 59.5, 60, 60.5, 61, 61.5, 62, 62.5, 63, 63.5, 64, 64.5, 65, 65.5, 66, 66.5, 67, 67.5, 68, 68.5, 69, 69.5, 70, 70.5, 71, 71.5, 72, 72.5, 73, 73.5, 74, 74.5, 75, 75.5, 76, 76.5, 77, 77.5, 78, 78.5, 79, 79.5, 80, 80.5, 81, 81.5, 82, 82.5, 83, 83.5, 84, 84.5, 85, 85.5, 86, 86.5, 87, 87.5, 88, 88.5, 89, 89.5, 90, 90.5, 91, 91.5, 92, 92.5, 93, 93.5, 94, 94.5, 95, 95.5, 96, 96.5, 97, 97.5, 98, 98.5, 99, 99.5, or 100% by weight of the composition.

In some embodiments, the final PQ content is about 0.1, 0.2, 0.3, 0.4, 0.5, 0.6, 0.7, 0.8, 0.9, 1, 1.5, 2, 2.5, 3, 3.5, 4, 4.5, 5, 5.5, 6, 6.5, 7, 7.5, 8, 8.5, 9, 9.5, 10, 10.5, 11, 11.5, 12, 12.5, 13, 13.5, 14, 14.5, 15, 15.5, 16, 16.5, 17, 17.5, 18, 18.5, 19, 19.5, 20, 20.5, 21, 21.5, 22, 22.5, 23, 23.5, 24, 24.5, 25, 25.5, 26, 26.5, 27, 27.5, 28, 28.5, 29, 29.5, 30, 30.5, 31, 31.5, 32, 32.5, 33, 33.5, 34, 34.5, 35, 35.5, 36, 36.5, 37, 37.5, 38, 38.5, 39, 39.5, 40, 40.5, 41, 41.5, 42, 42.5, 43, 43.5, 44, 44.5, 45, 45.5, 46, 46.5, 47, 47.5, 48, 48.5, 49, 49.5, 50, 50.5, 51, 51.5, 52, 52.5, 53, 53.5, 54, 54.5, 55, 55.5, 56, 56.5, 57, 57.5, 58, 58.5, 59, 59.5, 60, 60.5, 61, 61.5, 62, 62.5, 63, 63.5, 64, 64.5, 65, 65.5, 66, 66.5, 67, 67.5, 68, 68.5, 69, 69.5, 70, 70.5, 71, 71.5, 72, 72.5, 73, 73.5, 74, 74.5, 75, 75.5, 76, 76.5, 77, 77.5, 78, 78.5, 79, 79.5, 80, 80.5, 81, 81.5, 82, 82.5, 83, 83.5, 84, 84.5, 85, 85.5, 86, 86.5, 87, 87.5, 88, 88.5, 89, 89.5, 90, 90.5, 91, 91.5, 92, 92.5, 93, 93.5, 94, 94.5, 95, 95.5, 96, 96.5, 97, 97.5, 98, 98.5, 99, 99.5, or 100 wt. %.

In some embodiments, the final ion source content is about 0.1, 0.2, 0.3, 0.4, 0.5, 0.6, 0.7, 0.8, 0.9, 1, 1.5, 2, 2.5, 3, 3.5, 4, 4.5, 5, 5.5, 6, 6.5, 7, 7.5, 8, 8.5, 9, 9.5, 10, 10.5, 11, 11.5, 12, 12.5, 13, 13.5, 14, 14.5, 15, 15.5, 16, 16.5, 17, 17.5, 18, 18.5, 19, 19.5, 20, 20.5, 21, 21.5, 22, 22.5, 23, 23.5, 24, 24.5, 25, 25.5, 26, 26.5, 27, 27.5, 28, 28.5, 29, 29.5, 30, 30.5, 31, 31.5, 32, 32.5, 33, 33.5, 34, 34.5, 35, 35.5, 36, 36.5, 37, 37.5, 38, 38.5, 39, 39.5, 40, 40.5, 41, 41.5, 42, 42.5, 43, 43.5, 44, 44.5, 45, 45.5, 46, 46.5, 47, 47.5, 48, 48.5, 49, 49.5, 50, 50.5, 51, 51.5, 52, 52.5, 53, 53.5, 54, 54.5, 55, 55.5, 56, 56.5, 57, 57.5, 58, 58.5, 59, 59.5, 60, 60.5, 61, 61.5, 62, 62.5, 63, 63.5, 64, 64.5, 65, 65.5, 66, 66.5, 67, 67.5, 68, 68.5, 69, 69.5, 70, 70.5, 71, 71.5, 72, 72.5, 73, 73.5, 74, 74.5, 75, 75.5, 76, 76.5, 77, 77.5, 78, 78.5, 79, 79.5, 80, 80.5, 81, 81.5, 82, 82.5, 83, 83.5, 84, 84.5, 85, 85.5, 86, 86.5, 87, 87.5, 88, 88.5, 89, 89.5, 90, 90.5, 91, 91.5, 92, 92.5, 93, 93.5, 94, 94.5, 95, 95.5, 96, 96.5, 97, 97.5, 98, 98.5, 99, 99.5, or 100 wt. %.

In some embodiments, the weight ratio of PQ:NaOH is about 5:0.5, 5:1, 5:1.5, 5:2, 5:2.5, 5:3, 5:3.5, 5:4, 5:4.5, 5:5, 5:5.5, 5:6, 5:6.5, 5:7, 5:7.5, 5:8, 5:8.5, 5:9, 5:9.5, or 5:10.

In some embodiments, the weight ratio of PQ:[EMIM]Cl is about 1:0.5, 1:1, 1:1.5, 1:2, 1:2.5, 1:3, 1:3.5, 1:4, 1:4.5, 1:5, 1:5.5, 1:6, 1:6.5, 1:7, 1:7.5, 1:8, 1:8.5, 1:9, 1:9.5, or 1:10.

In some embodiments, the step of drying the hydrogel composition to a gel state is performed at about 0, 10, 20, 30, 40, 50, 60, 70, 80, 90, or 100° C.

In some embodiments, the duration of drying the hydrogel composition to a gel state is about 0.5, 1, 2, 3, 4, 5, 6, 7, 8, 9, 10, 15, 20, 25, 30, 35, 40 45, or 50 hours.

Although the description referred to particular embodiments, the disclosure should not be construed as limited to the embodiments set forth herein.

### Numbered Embodiments 1

Embodiment 1. A thermometric hydrogel composition for thermal sensor, comprising: (a) at least one polyquaternium (PQ) comprising at least one quaternary ammonium group; (b) at least one ion source; and (c) a solvent.

Embodiment 2. The composition of any one of the preceding embodiments, wherein the at least one ion source comprises one or more acids, alkalis, salts, ionic liquids, and/or combination thereof.

Embodiment 3. The composition of any one of the preceding embodiments, wherein the solvent is water, ionic liquids, ethanol, ethylene glycol, dimethyl sulfoxide, or combination thereof.

Embodiment 4. The composition of any one of the preceding embodiments, wherein the composition is dried to a water content of about 14-55 wt. % to form a PQ based ionic hydrogel, wherein final PQ and ion source contents are in the ranges of 15-72 wt. % and 7-58 wt. %, respectively.

Embodiment 5. The composition of any one of the preceding embodiments, wherein the at least one ion source is sodium hydroxide (NaOH) and the weight ratio of PQ:NaOH is about 5:1 to 5:8.

Embodiment 6. The composition of any one of the preceding embodiments, wherein the PQ is polyquaternium-10 (PQ-10) which is about 3-4% by weight; and the NaOH is about 0.6-4.9% by weight of the composition, wherein the composition has a pH value of about 13-14.

Embodiment 7. The composition of any one of the preceding embodiments, wherein the at least one ion source is 1-ethyl-3-methylimidazolium chloride ([EMIM]Cl) and the weight ratio of PQ:[EMIM]Cl is about 1:0.5 to 1:2.

Embodiment 8. The composition of any one of the preceding embodiments, wherein the PQ is PQ-10 which is about 7.7-8.7% by weight; and the [EMIM]Cl is about 4.3-15.4% by weight of the composition, wherein the composition has a pH value of about 4-11.

Embodiment 9. A method of preparing a thermometric hydrogel composition for thermal sensor, comprising the step of: (a) mixing at least one polyquaternium (PQ) into a solution comprising at least one ion source to form a mixture; (b) adjusting the pH value of the mixture to form a composition; (c) drying the composition to a gel state, such that a PQ based ionic hydrogel is formed.

Embodiment 10. The method of any one of the preceding embodiments, wherein the at least one ion source comprises one or more acids, alkalis, salts, ionic liquids, and/or combination thereof.

Embodiment 11. The method of any one of the preceding embodiments, wherein the at least one ion source is NaOH and the weight ratio of PQ:NaOH is about 5:1 to 5:8.

Embodiment 12. The method of any one of the preceding embodiments, wherein the composition comprises: the PQ is PQ-10 of about 3-4% by weight; and the NaOH of about 0.6-4.9% by weight of the composition, wherein the pH value is adjusted to about 13-14.

Embodiment 13. The method of any one of the preceding embodiments, wherein the step c) drying the composition to gel state is performed at about 40° C. for 20-50 hours, until the water content is about in the range of 14-55 wt. %.

Embodiment 14. The method of any one of the preceding embodiments, wherein the at least one ion source is [EMIM]Cl and the weight ratio of PQ:[EMIM]Cl is about 1:0.5 to 1:2.

Embodiment 15. The method of any one of the preceding embodiments, wherein the composition comprises: the PQ is PQ-10 of about 7.7-8.7% by weight; and the [EMIM]Cl of about 4.3-15.4% by weight of the composition, wherein the pH value is adjusted to about 4-11.

Embodiment 16. A flexible thermal sensor, comprising: (a) a flexible substrate; (b) a first flexible printed circuit board (FPCB) that is disposed on the flexible substrate, the first FPCB comprising: (i) a plurality of first electrodes; and (ii) a plurality of first connecting lines, wherein the individual first electrode is in electrical communication with the individual first connecting line; (c) a mask layer that is disposed on the first FPCB; (d) at least one PQ based ionic hydrogel; and (e) an insulating layer that is disposed onto the first FPCB, wherein the mask layer comprises at least one receiving portion, defining at least one space that is sized and shaped large enough to receive at least a portion of the first electrodes and at least one remaining space to receive the at least one PQ based ionic hydrogel, such that at least a portion of the first electrodes is in electrical communication with the at least one PQ based ionic hydrogel.

Embodiment 17. The sensor of any one of the preceding embodiments, wherein the mask layer comprises one receiving portion, defining one space sized and shaped large enough to receive the plurality of first electrodes, and the remaining space is sized and shaped large enough to receive one PQ based ionic hydrogel to at least cover the plurality of first electrodes, such that the plurality of first electrodes are in electrical communication with each other through the PQ based ionic hydrogel.

Embodiment 18. The sensor of any one of the preceding embodiments, further comprising a second flexible printed circuit board (FPCB), the second FPCB comprising: a plurality of second electrodes; and a plurality of second connecting lines, wherein individual second electrode is in electrical communication with individual second connecting line, wherein each of the plurality of second electrodes is positioned juxtapose to the corresponding first electrode, wherein the second FPCB is disposed on the first FPCB and below the insulating layer, and wherein the mask layer comprises a plurality of receiving portions, defining a plurality of spaces, individual space is sized and shaped large enough to receive individual first electrode and individual second electrode, and the remaining space between the first electrode and the second electrode is sized and shaped large enough to receive PQ based ionic hydrogel therebetween, such that the first electrode is in electrical communication with the second electrode through the PQ based ionic hydrogel.

Embodiment 19. The sensor of any one of the preceding embodiments, wherein at least one electrode is a sensing electrode and at least another one electrode is a reference electrode.

Embodiment 20. The sensor of any one of the preceding embodiments, wherein the PQ based ionic hydrogel comprises a composition as described in any one of the embodiments 1-8.

Embodiment 21. The sensor of any one of the preceding embodiments, wherein the PQ based ionic hydrogel is prepared by a method as described in any one of the embodiments 9-15.

Embodiment 22. A method of making a flexible thermal sensor, comprising: (a) providing a first flexible printed circuit board (FPCB) onto a flexible substrate, wherein the first FPCB comprises a plurality of first electrodes and a plurality of first connecting lines, wherein the individual first electrode is in electrical communication with the individual first connecting line; (b) attaching at least one mask layer onto the first FPCB, wherein the mask layer comprises at least one receiving portion, defining at least one space that is sized and shaped large enough to receive at least a portion of the first electrodes and at least one remaining space to receive at least one PQ based ionic hydrogel; (c) casting a thermometric hydrogel composition comprising at least one dissolved PQ and at least one ion source onto the at least one remaining space; (d) drying the composition to a gel state to form the at least one PQ based ionic hydrogel, such that at least a portion of the first electrodes is in electrical communication with the at least one PQ based ionic hydrogel; (e) attaching an insulating layer onto the first FPCB.

Embodiment 23. The method of any one of the preceding embodiments, further comprising a step of attaching a second flexible printed circuit board (FPCB) onto the first FPCB and below the insulating layer, prior to step (e), wherein the second FPCB comprises a plurality of second electrodes and a plurality of second connecting lines, wherein the individual second electrode is in electrical communication with the individual second connecting line, wherein each of the plurality of second electrodes is positioned juxtapose to the corresponding first electrode, and wherein the mask layer includes a plurality of receiving portions, defining a plurality of spaces, individual space is sized and shaped large enough to receive individual first electrode and individual second electrode, and the remaining space between the first electrode and the second electrode is sized and shaped large enough to receive PQ based ionic hydrogel therebetween, such that the first electrode is in electrical communication with the second electrode through the PQ based ionic hydrogel.

Embodiment 24. The method of any one of the preceding embodiments, wherein at least one electrode is a sensing electrode and at least another one electrode is a reference electrode.

Embodiment 25. The method of any one of the preceding embodiments, wherein the PQ based ionic hydrogel comprises a composition as described in any one of the preceding embodiments 1-8.

Embodiment 26. The method of any one of the preceding embodiments, wherein the PQ based ionic hydrogel is prepared by the method as described in any one of the embodiments 9-15.

### Numbered Embodiments 2

Embodiment 1. A thermometric hydrogel composition for thermal sensor, comprising: (a) polyquaternium-10 (PQ-10); (b) at least one ion source; and (c) water.

Embodiment 2. The composition of embodiment 1, wherein the at least one ion source comprises one or more acids, alkalis, salts, ionic liquids, and/or combination thereof.

Embodiment 3. The composition of any one of the preceding embodiments, wherein the composition is dried to a water content of about 14-55 wt. % to form a PQ based ionic hydrogel.

Embodiment 4. The composition of any one of the preceding embodiments, wherein the at least one ion source is sodium hydroxide (NaOH) and the weight ratio of PQ-10:NaOH is about 5:1 to 5:8.

Embodiment 5. The composition of any one of the preceding embodiments, wherein the PQ-10 is about 3-4% by weight; and the NaOH is about 0.6-4.9% by weight of the composition, wherein the composition has a pH value of about 13-14.

Embodiment 6. The composition of any one of the preceding embodiments, wherein the at least one ion source is 1-ethyl-3-methylimidazolium chloride ([EMIM]Cl) and the weight ratio of PQ-10: [EMIM]Cl is about 1:0.5 to 1:2.

Embodiment 7. The composition of any one of the preceding embodiments, wherein the PQ-10 is about 7.7-8.7% by weight; and the [EMIM]Cl is about 4.3-15.4% by weight of the composition, wherein the composition has a pH value of about 4-11.

Embodiment 8. A method of preparing a thermometric hydrogel composition for thermal sensor, comprising the step of: (a) mixing polyquaternium-10 (PQ-10) powder into an aqueous solution comprising at least one ion source to form a mixture; (b) adjusting the pH value of the mixture to form a composition; (c) drying the composition to a gel state, such that a PQ based ionic hydrogel is formed.

Embodiment 9. The method of embodiment 8, wherein the at least one ion source comprises one or more acids, alkalis, salts, ionic liquids, and/or combination thereof.

Embodiment 10. The method of any one of the embodiments 8-9, wherein the at least one ion source is NaOH and the weight ratio of PQ-10:NaOH is about 5:1 to 5:8.

Embodiment 11. The method of any one of the preceding embodiments 8-10, wherein the composition comprises: the PQ-10 of about 3-4% by weight; and the NaOH of about 0.6-4.9% by weight of the composition, wherein the pH value is adjusted to about 13-14.

Embodiment 12. The method of any one of the preceding embodiments 8-11, wherein the step c) drying the composition to gel state is performed at about 40° C. for 20-50 hours, until the water content is about in the range of 14-55 wt. %.

Embodiment 13. The method of any one of the preceding embodiments 8-12, wherein the at least one ion source is [EMIM]Cl and the weight ratio of PQ-10: [EMIM]Cl is about 1:0.5 to 1:2.

Embodiment 14. The method of any one of the embodiments 8-13, wherein the composition comprises: the PQ-10 of about 7.7-8.7% by weight; and the [EMIM]Cl of about 4.3-15.4% by weight of the composition, wherein the pH value is adjusted to about 4-11.

Embodiment 15. A flexible thermal sensor, comprising: (a) a flexible substrate; (b) a first flexible printed circuit board (FPCB) that is disposed on the flexible substrate, the first FPCB comprising: (i) a plurality of first electrodes; and (ii) a plurality of first connecting lines, wherein individual first electrode is in electrical communication with individual first connecting line; (c) a mask layer that is disposed on the first FPCB; (d) at least one PQ based ionic hydrogel; and (e) an insulating layer that is disposed onto the first FPCB, wherein the mask layer comprises at least one receiving portion, defining at least one space that is sized and shaped large enough to receive at least a portion of the first electrodes and at least one remaining space to receive the at least one PQ based ionic hydrogel, such that at least a portion of the first electrodes is in electrical communication with the at least one PQ based ionic hydrogel.

Embodiment 16. The sensor of embodiment 15, wherein the mask layer comprises one receiving portion, defining one space sized and shaped large enough to receive the plurality of first electrodes, and the remaining space is sized and shaped large enough to receive one PQ based ionic hydrogel to at least cover the plurality of first electrodes, such that the plurality of first electrodes are in electrical communication with each other through the PQ based ionic hydrogel.

Embodiment 17. The sensor of any one of the embodiments 15-16, further comprising a second flexible printed circuit board (FPCB), the second FPCB comprising: a plurality of second electrodes; and a plurality of second connecting lines, wherein individual second electrode is in electrical communication with individual second connecting line, wherein each of the plurality of second electrodes is positioned juxtapose to the corresponding first electrode, wherein the second FPCB is disposed on the first FPCB and below the insulating layer, and wherein the mask layer comprises a plurality of receiving portions, defining a plurality of spaces, individual space is sized and shaped large enough to receive individual first electrode and individual second electrode, and the remaining space between the first electrode and the second electrode is sized and shaped large enough to receive PQ based ionic hydrogel therebetween, such that the first electrode is in electrical communication with the second electrode through the PQ based ionic hydrogel.

Embodiment 18. The sensor of any one of the embodiments 15-17, wherein at least one electrode is a sensing electrode and at least another one electrode is a reference electrode.

Embodiment 19. The sensor of any one of the embodiments 15-18, wherein the PQ based ionic hydrogel comprises a composition as described in any one of the embodiments 1-7.

Embodiment 20. The sensor of any one of the embodiments 15-19, wherein the PQ based ionic hydrogel is prepared by a method as described in any one of the embodiments 8-14.

Embodiment 21. A method of making a flexible thermal sensor, comprising: (a) providing a first flexible printed circuit board (FPCB) onto a flexible substrate, wherein the first FPCB comprises a plurality of first electrodes and a plurality of first connecting lines, wherein individual first electrode is in electrical communication with individual first connecting line; (b) attaching at least one mask layer onto the first FPCB, wherein the mask layer comprises at least one receiving portion, defining at least one space that is sized and shaped large enough to receive at least a portion of the first electrodes and at least one remaining space to receive at least one PQ based ionic hydrogel; (c) casting a thermometric hydrogel composition comprising at least one dissolved PQ and at least one ion source onto the at least one remaining space; (d) drying the composition to a gel state to form the at least one PQ based ionic hydrogel, such that at least a portion of the first electrodes is in electrical communication with the at least one PQ based ionic hydrogel; (e) attaching an insulating layer onto the first FPCB.

Embodiment 22. The method of embodiment 21, further comprising a step of attaching a second flexible printed circuit board (FPCB) onto the first FPCB and below the insulating layer, prior to step (e), wherein the second FPCB comprises a plurality of second electrodes and a plurality of second connecting lines, wherein individual second electrode is in electrical communication with individual second connecting line, wherein each of the plurality of second electrodes is positioned juxtapose to the corresponding first electrode, and wherein the mask layer includes a plurality of receiving portions, defining a plurality of spaces, individual space is sized and shaped large enough to receive individual first electrode and individual second electrode, and the remaining space between the first electrode and the second electrode is sized and shaped large enough to receive PQ based ionic hydrogel therebetween, such that the first electrode is in electrical communication with the second electrode through the PQ based ionic hydrogel.

Embodiment 23. The method of any one of the embodiments 21-22, wherein at least one electrode is a sensing electrode and at least another one electrode is a reference electrode.

Embodiment 24. The method of any one of the embodiments 21-23, wherein the PQ based ionic hydrogel comprises a composition as described in any one of the embodiments 1-7.

Embodiment 25. The method of any one of the embodiments 21-24, wherein the PQ based ionic hydrogel is prepared by the method as described in any one of the embodiments 8-14.

### EXAMPLES

Provided herein are examples that describe in more detail certain embodiments of the present disclosure. The examples provided herein are merely for illustrative purposes and are not meant to limit the scope of the invention in any way. All references given below and elsewhere in the present application are hereby included by reference.

### Example 1: General Composition and Preparation of PQ Based Ionic Hydrogels

In this example, provided is a general thermometric hydrogel composition for thermal sensor containing polyquaternium (PQ), at least one ion source, and water. In the following examples, such thermometric hydrogel and thermometric hydrogel compositions may be referred to as PQ based ionic hydrogel and PQ based ionic hydrogel compositions, respectively. The at least one ion source contains one or more acids, alkalis, salts, ionic liquids, and/or combination thereof. In some examples, the hydrogel composition is dried to form an ionic hydrogel (or PQ based ionic hydrogel).

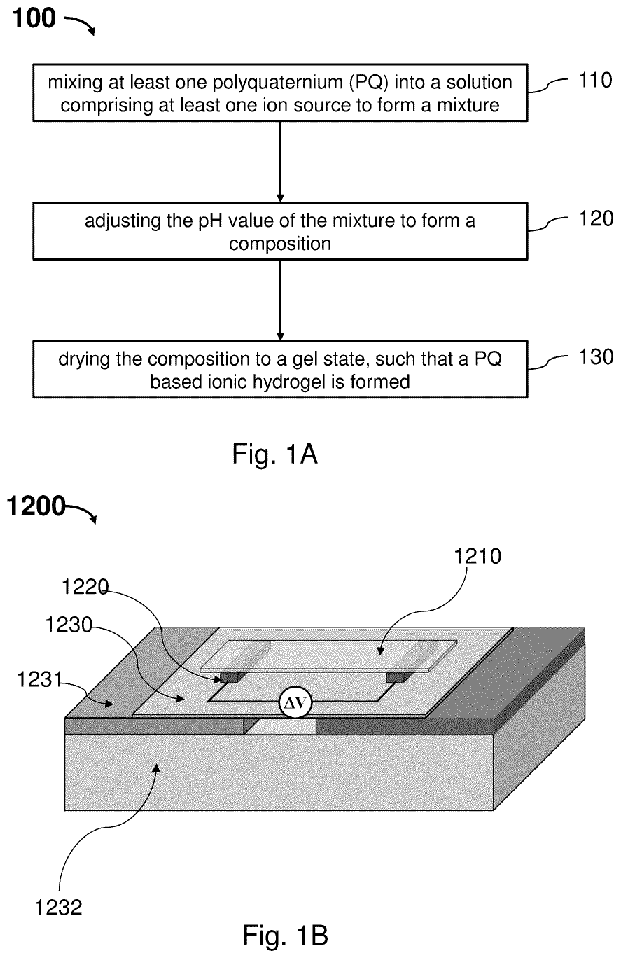

Now referring to FIG. 1A, the example general method 100 of preparing a thermometric hydrogel composition for thermal sensor is illustrated. In this example the steps are in sequential order, starting from block 110 to 130.

The first step stated in block 110 is mixing at least one polyquaternium (PQ) such as polyquaternium-10 (PQ-10) powders into a solution comprising at least one ion source to form a mixture.

The second step stated in block 120 is adjusting the pH value of the mixture to form a composition.

The third step stated in block 130 is drying the composition to a gel state, such that a PQ based ionic hydrogel is formed.

In this example, the composition is dried to form a PQ based ionic hydrogel. In one example, the water content can be in the range of 14-55 wt. %, and the final PQ-10 and ion source contents are in the ranges of 15-72 wt. % and 7-58 wt. %, respectively.

Now referring to FIG. 1B, the capability of the PQ based ionic hydrogels for thermal sensing was characterized by measuring the potential difference between the hot and cold ends of the PQ based ionic hydrogel sample through a schematic setup 1200. In this example, a free-standing PQ based ionic hydrogel 1210 is cut into a rectangular shape for thermopower characterization. The PQ based ionic hydrogel 1210 was suspended between two graphite electrodes 1220, which were fixed on a glass substrate 1230. Two Peltier modules 1231 were adhered to the backside of the glass substrate 1230 to generate a temperature gradient across the PQ based ionic hydrogel sample, and the other side of the Peltier modules 1231 were attached to a heat sink 1232. The temperatures at the hot (T_{H}) and cold (T_{C}) ends of the sample were measured by two thermocouples taped onto the top surface of graphite electrodes 1220. The open-circuit voltage between two graphite electrodes was recorded. For each temperature difference, the temperatures at both ends and the open-circuit voltage were continuously measured until reaching the steady state. The measured open-circuit voltage (ΔV=V_{H}−V_{C}) and temperature difference (ΔT=T_{H}−T_{C}) were used to determine the thermopower of an example PQ based ionic hydrogel.

### Example 2: Preparation of Example PQ Based Ionic Hydrogels with NaOH as Ion Source

In some examples, the PQ based ionic hydrogel composition with NaOH as ion source is an aqueous solution containing PQ-10 of about 3-4 wt. % and NaOH of about 0.6-4.9 wt. %. with a pH value of about 13-14. In one example, the composition comprises 1.3 wt. % NaOH and 3.2 wt. % PQ-10 in water at a pH value of 13-14. In some examples, the final PQ-10 and NaOH contents in the ionic hydrogel (after drying) are in the ranges of 17-72 wt. % and 7-53 wt. %, respectively.

In this example, the example method of preparing a PQ based ionic hydrogel with NaOH as the ion source for a weight ratio of PQ-10:NaOH around 5:2 comprises the steps as follows. First, about 0.2 g NaOH was dissolved in 15 mL deionized water. Then, about 0.5 g PQ-10 dry powders were added into the prepared NaOH solution under magnetic stirring. The solution was stirred at room temperature for at least 12 hours until a homogeneous solution is formed. The PQ-10/NaOH mixture was poured into a container such as a petri dish and then subjected to a drying process at about 40° C. The water content in the PQ-10/NaOH ionic hydrogel can be adjusted by controlling the drying duration. When the water content was roughly in the range of about 14-55 wt. %, corresponding to drying at about 40° C. for about 20-50 hours, the PQ-10/NaOH ionic hydrogel was peeled off from the petri dish as a free-standing hydrogel film.

In some other examples, the weight ratio of PQ-10 to NaOH ranges from 5:1 to 5:8, which can provide sufficient ion sources and meanwhile prevent severe precipitation of NaOH in the PQ-10 matrix. The pH value of the prepared ionic solutions with the aforementioned PQ-10:NaOH weight ratios ranges from 13 to 14.

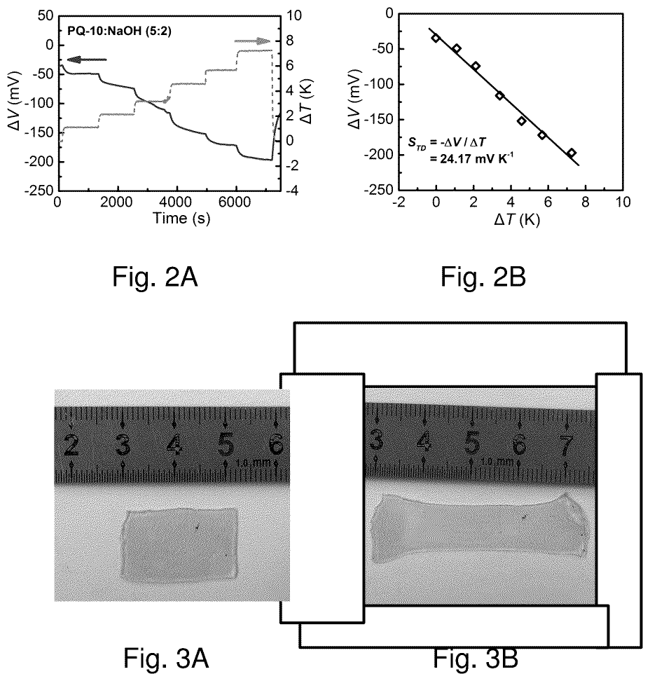

Now referring to FIGS. 2A and 2B, which show the measured open-circuit voltage (ΔV=V_{H}−V_{C}) and temperature difference (ΔT=T_{H}−T_{C}) (according to the schematic setup 1200 as described in Example 1) for the example ionic hydrogel with PQ-10:NaOH=5:2 prepared as described above in this Example 2. With the increase of ΔT, ΔV shows a step decrease accordingly in FIG. 2A, indicating the conversion of temperature variation into an electrical signal. The thermopower of the developed example ionic hydrogel is defined as S_{TD}=−ΔV/ΔT, which can be determined from the slope of the linear fitting line shown in FIG. 2B. The positive sign of the thermopower indicates that the PQ-10/NaOH hydrogel is a p-type material where Na⁺ ions have higher thermal mobility than OH⁻. In this example, the thermopower of the example PQ-10/NaOH ionic hydrogel with a PQ-10:NaOH weight ratio of 5:2 reached 24.17 mV/K, which was much higher than that of the commonly used materials for thermocouples.

### Example 3: Preparation of PQ Based Ionic Hydrogels with [EMIM]Cl as Ion Source

In some examples, the PQ based ionic hydrogel composition with [EMIM]Cl as ion source is an aqueous solution comprising 4.3-15.4 wt. % [EMIM]Cl and 7.7-8.7 wt. % PQ-10 at a pH value of about 4-11. In some embodiments, the final PQ-10 and [EMIM]Cl contents in the ionic hydrogel (after drying) are in the ranges of 15-58 wt. % and 15-58 wt. %, respectively.

In this example, the hydrogel composition contains about 12 wt. % [EMIM]Cl and about 8 wt. % PQ-10 in water. In this example, the method of preparing a PQ based ionic hydrogel with [EMIM]Cl as the ion source for an example weight ratio of about 1:1.5 includes the steps as follows. About 1 g PQ-10 and 1.5 g [EMIM]Cl powders were dissolved in 10 mL deionized water under magnetic stirring. A certain amount of hydrochloric acid (HCl) or NaOH was added into the solution for tuning the pH value. The pH value of the prepared ionic solution ranges from 4 to 11. The homogeneous solution is then poured into a container such as a petri dish, followed by a drying process. The free-standing ionic hydrogel is obtained by cutting and peeling off the film from the petri dish. In other examples, the weight ratio of PQ-10 to [EMIM]Cl is in the range of about 1:0.5 to 1:2, the water content of the ionic hydrogel is about 14-55%.

FIGS. 3A and 3B show the photographs of a piece of the example PQ-10/[EMIM]Cl ionic hydrogel with a weight ratio of about 1:1.5 (prepared as described above in this Example 3) before and after being stretched, respectively, which indicates the gel-like mechanical properties of the prepared film.

The example PQ based ionic hydrogels with other ion sources can also achieve high thermopower. In one example, example PQ-10/[EMIM]Cl ionic hydrogels with weight ratios of 1:0.5 and 1:2 was prepared as described above in this example, respectively. Results showed that the incorporation of [EMIM]Cl into PQ-10 led to a thermopower of 7.79 mV/K for the weight ratio of 1:1 at a pH value of 11, indicating that ionic liquids such as [EMIM]Cl are also effective ion sources for PQ based thermometric ionic hydrogels.

### Example 4: General Flexible Thermal Sensor and Method of Making Thereof

In this example, provided is a general example flexible thermal sensor containing a flexible substrate, a first flexible printed circuit board (FPCB) that is disposed on the flexible substrate, a mask layer that is disposed on the first FPCB, at least one PQ based ionic hydrogel and an insulating layer that is disposed onto the first FPCB. The first FPCB contains a plurality of first electrodes and a plurality of first connecting lines. The individual first electrode is in electrical communication with the individual first connecting line. The mask layer comprises at least one receiving portion, defining at least one space that is sized and shaped large enough to receive at least a portion of the first electrodes and at least one remaining space to receive the at least one PQ based ionic hydrogel, such that at least a portion of the first electrodes is in electrical communication with the at least one PQ based ionic hydrogel. The PQ based ionic hydrogel can be a hydrogel prepared by a hydrogel composition of any one as described in previous Examples 1-3.

In some examples, the general method of making the flexible thermal sensor contains the following steps: (A) Customizing a FPCB. (B) Placing the FPCB on a flexible substrate, aligning and attaching a mask layer onto the top surface. (C) Drop casting the prepared ionic solution onto the exposed region (or remaining space) of the mask layer. (D) Drying the solution at room temperature to obtain the ionic hydrogel. (E) Covering the sensor array with an insulating layer.

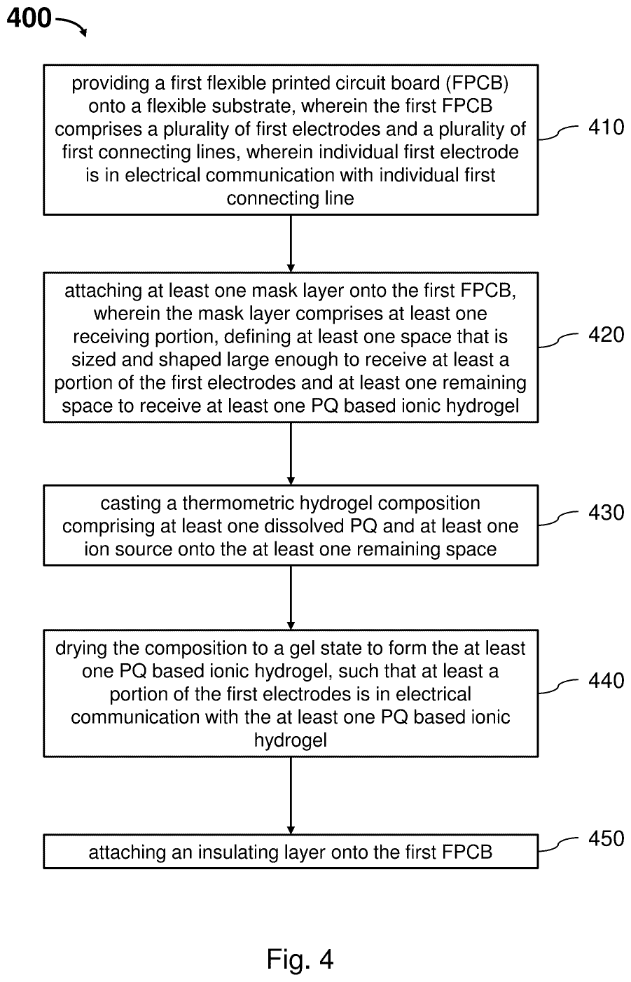

Now referring to FIG. 4, an example method 400 of making a flexible thermal sensor is illustrated. In this example, the steps are in sequential order, starting from block 410 to 450.

The first step stated in block 410 is providing a first flexible printed circuit board (FPCB) onto a flexible substrate, wherein the first FPCB comprises a plurality of first electrodes and a plurality of first connecting lines, wherein the individual first electrode is in electrical communication with the individual first connecting line.

The second step stated in block 420 is attaching at least one mask layer onto the first FPCB, wherein the mask layer comprises at least one receiving portion, defining at least one space that is sized and shaped large enough to receive at least a portion of the first electrodes and at least one remaining space to receive at least one PQ based ionic hydrogel. In some examples, the at least one mask layer is aligned to cover at least a portion of the first FPCB. In some examples, the at least one mask layer is a tape made of polyimide (PI), or acrylic (e.g., 3M VHB tape), or combination thereof, which is attached to the first FPCB by adhesion.

The third step stated in block 430 is casting a thermometric hydrogel composition comprising at least one dissolved PQ (such as PQ-10) and at least one ion source onto the at least one remaining space. In some examples, the thermometric hydrogel composition is any one of the compositions as described herein. In some examples, the thermometric hydrogel composition undergoes a pH adjustment as described herein.

The fourth step stated in block 440 is drying the hydrogel composition to a gel state to form the at least one PQ based ionic hydrogel, such that at least a portion of the first electrodes is in electrical communication with the at least one PQ based ionic hydrogel. In some examples, the hydrogel composition is dried to form a PQ based ionic hydrogel which comprises a water content in the range of 14-55 wt. %, and the final PQ-10 and ion source contents are in the ranges of 15-72 wt. % and 7-58 wt. %, respectively. In some examples, the final PQ-10 and NaOH contents are in the ranges of 17-72 wt. % and 7-53 wt. %, respectively. In some examples, the final PQ-10 and [EMIM]Cl contents are in the ranges of 15-58 wt. % and 15-58 wt. %, respectively. In some examples, the hydrogel is prepared from any one of the thermometric hydrogel compositions as described herein.

The fifth step stated in block 450 is attaching an insulating layer onto the first FPCB, such that the flexible thermal sensor is formed.

Other example methods are described in the following examples.

### Example 5: Flexible Thermal Sensors Based on Example Ionic Hydrogels (In-Plane Configurations)

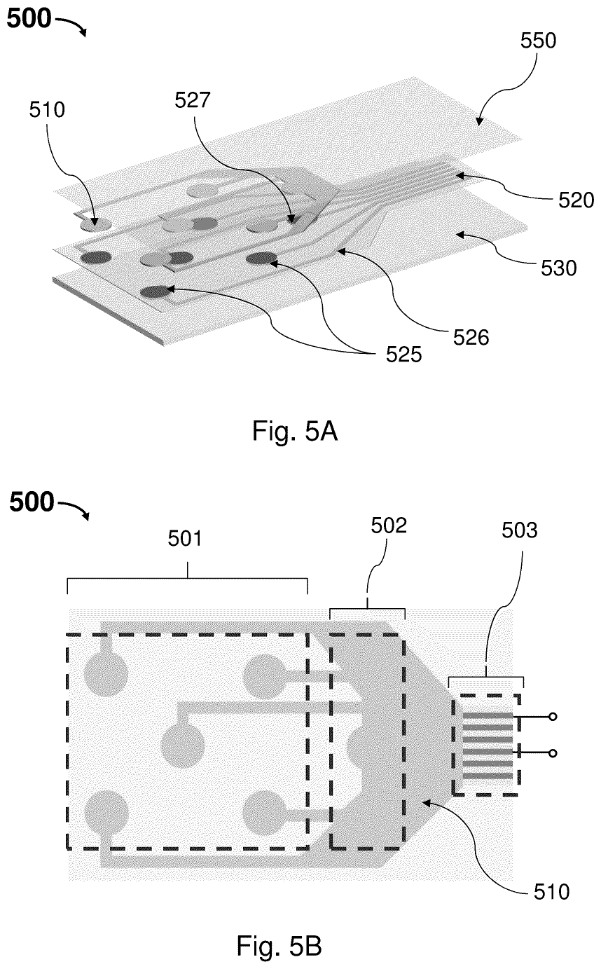

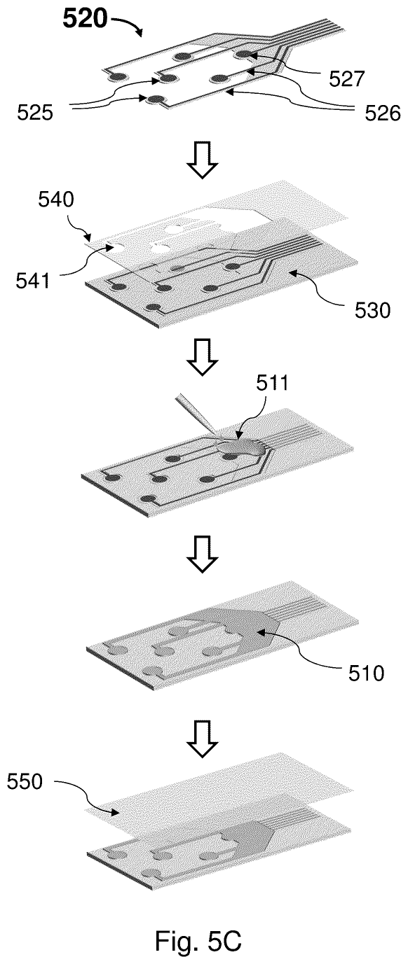

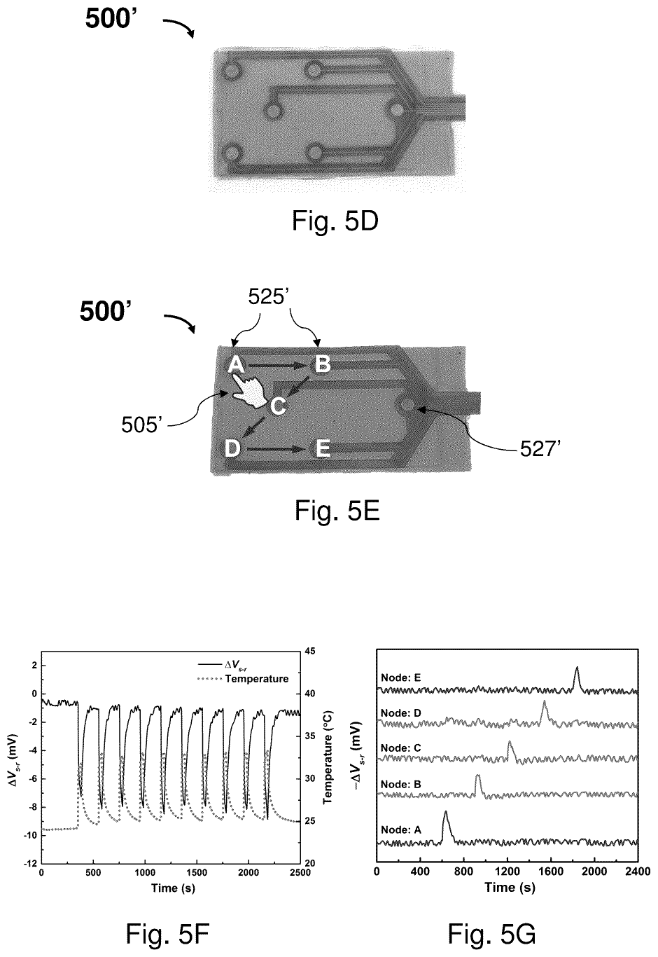

Now referring to FIGS. 5A-5C, the schematic of an example in-plane flexible thermal sensor 500 is shown. From the bottom to the top sequentially, the example in-plane flexible thermal sensor 500 generally contains a flexible substrate 530, a first flexible printed circuit board (FPCB) 520, a mask layer 540, PQ based ionic hydrogel 510 and an insulating layer 550, all of which are substantially in the form of a flat sheet, respectively. The mask layer 540 contains a receiving portion, defining at least one space that is sized and shaped large enough to receive at least a portion of the first electrodes and at least one remaining space to receive the at least one PQ based ionic hydrogel. In this example, PQ based ionic hydrogel 510 is one integral piece with the size and shape defined by the remaining space of the receiving portion of the mask layer 540. The size and shape of the receiving portion substantially match the profile of at least a portion of the first FPCB 520. The PQ based ionic hydrogel 510 was patterned onto a customized first FPCB 520, which contains five electrodes 525 (also referred as sensor nodes) spaced apart from each other in one plane, a reference electrode 527 and six connecting lines 526. Each first connecting line 526 is in electrical connection with a first electrode 525 or a reference electrode 527. In the example shown in FIGS. 5A-5C, the top surface of the flexible thermal sensor 500 is covered by an insulating layer 550 to minimize the effect of the ambient environment on the sensor array and thereby improve the stability. Any suitable flexible and insulating materials can be used as the insulating layer 550, such as polyimide (PI), polyethylene (PE), polytetrafluoroethylene (PTFE), or polyvinylidene chloride (PVDC), or combination thereof.

As schematically shown in FIG. 5B, the flexible thermal sensor 500 contains a sensing electrode portion 501, a common reference electrode portion 502 and a connecting portion 503 which is connectable to an external circuit. The sensing electrode portion 501 includes the plurality of electrodes 525, and the common reference electrode portion 502 includes a reference electrode 527.

During operation, the reference electrode can be optionally in contact with a heat sink (or heat spreader, not shown) to stabilize its thermal condition. Once a thermal stimulus is exerted onto one of the plurality of electrodes 525, a potential difference (ΔVₛ₋ᵣ) will be generated in the PQ based ionic hydrogel 510 between the corresponding electrode 525 and the reference electrode 527 due to the unbalanced diffusion of cations and anions under a temperature gradient, which will reveal the thermal condition at the electrode 525 accordingly.

Now referring to FIG. 5C, an example fabrication process of an example flexible thermal sensor 500 (or an in-plane flexible temperature sensor array) is schematically shown and described as follows. As shown in FIG. 5C, a first flexible printed circuit board (FPCB) 520 containing a plurality of first electrodes 525 (in this example, 5 electrodes), a reference electrode 527, and a plurality of first connecting lines 526 (in this example, 6 first connecting lines) was first customized. The first flexible printed circuit board (FPCB) 520 was placed on a flexible substrate 530 (e.g. PI, polydimethylsiloxane (PDMS), Ecoflex, rubber, etc.). Then, a flexible mask layer 540 (e.g. PI tape, 3M VHB tape, etc.) with a receiving portion 541 which is a space with a designed pattern aligned with the first flexible printed circuit board (FPCB) 520 was disposed onto the first flexible printed circuit board (FPCB) 520. In some examples, the receiving portion 541 of the mask layer 540 is fabricated through laser cutting, punching, 3D printing, or other methods, and the receiving portion 541 defines at least one space that is sized and shaped large enough to receive at least one electrode 525 and to form at least one remaining space in the receiving portion 541 for receiving any one of the hydrogel composition 511 for the formation of the PQ based ionic hydrogel 510 as described herein. Next, a hydrogel composition 511 (e.g., an example ionic hydrogel composition of PQ-10/NaOH) was drop casted onto the receiving portion 541, filling the remaining space defined by the receiving portion 541 of the mask layer 540 after disposed onto the first flexible printed circuit board (FPCB) 520. Upon drying (for example, in ambient environment for 2 days), a patterned PQ based ionic hydrogel 510 was formed in the remaining space defined by the receiving portion 541 of the mask layer 540 (in other words, the exposed region (or remaining space) of the receiving portion of the mask layer) on the first flexible printed circuit board (FPCB) 520, such that the plurality of electrodes 525 are in electrical communication with each other through the formed PQ based ionic hydrogel 510. Finally, the top surface of the flexible thermal sensor 500 including the sensing electrode portion 501, the common reference electrode portion 502 and a portion of the connecting portion 503 are covered by an insulating layer 550 for packaging.

During operation, in some examples, the electrodes 525 and reference electrode 527 are connectable to a data logger through a multi-channel connector and the ΔVₛ₋ᵣ for all of the plurality of electrodes 525 can be simultaneously recorded.

A photograph of the resulting flexible thermal sensor 500′ is shown in FIG. 5D.

Now referring to FIGS. 5E-5G, the thermal sensing capability of the example flexible thermal sensor 500′ was demonstrated. During testing, each of the plurality of electrodes 525′ (i.e., electrodes or sensor nodes A-E) was tapped by a finger 505′ in sequential order as illustrated in FIG. 5E. Now referring to FIG. 5F, the potential difference ΔVₛ₋ᵣ and the temperature recorded for the cyclic finger touch-release test on one of the electrodes (or sensor nodes) A-E were shown. The potential difference was recorded by a data logger, and the real-time temperature at the sensor node was monitored by a type K thermocouple. Results showed that in response to the temperature stimulus exerted by the finger 505′, the recorded potential difference showed an immediate drop at the moment of touching and quickly rebounded once the finger 505′ was retracted from the sensor surface. There is a good agreement between the potential difference and temperature stimulus, indicating great sensitivity and repeatability of the example flexible thermal sensor 500′ which contains the PQ based ionic hydrogel.

The spatial thermal sensing of the example flexible thermal sensor 500′ is demonstrated through a sequential finger touch-release test of each of the plurality of electrodes 525′ (i.e., electrodes or sensor nodes A-E), as shown in FIG. 5G. When a specific electrode 525′ was touched by a finger, the potential difference between the corresponding electrode 525′ and the reference electrode 527′ showed an obvious peak, while the signals remain nearly unchanged for other channels. As a result, the time and location of the finger contact with the sensor array can be simply determined through simultaneously monitoring the signals of all channels.

### Example 6: Flexible Thermal Sensors Based on Example Ionic Hydrogels (Cross-Plane Configurations)

In some embodiments, flexible thermal sensors with cross-plane configurations can be prepared by the following general method that contains the following steps: (A) Customizing the bottom (or first) FPCB. (B) Placing the bottom FPCB on a flexible substrate, aligning and attaching a mask layer onto the top surface. (C) Drop casting the prepared ionic solution (or a hydrogel composition) onto the exposed region of the mask layer. (D) Drying the solution at room temperature to obtain the ionic hydrogel (or PQ based ionic hydrogel). (E) Aligning and attaching the top (or second) FPCB to the ionic hydrogel. (F) Covering the sensor array with an insulating layer.

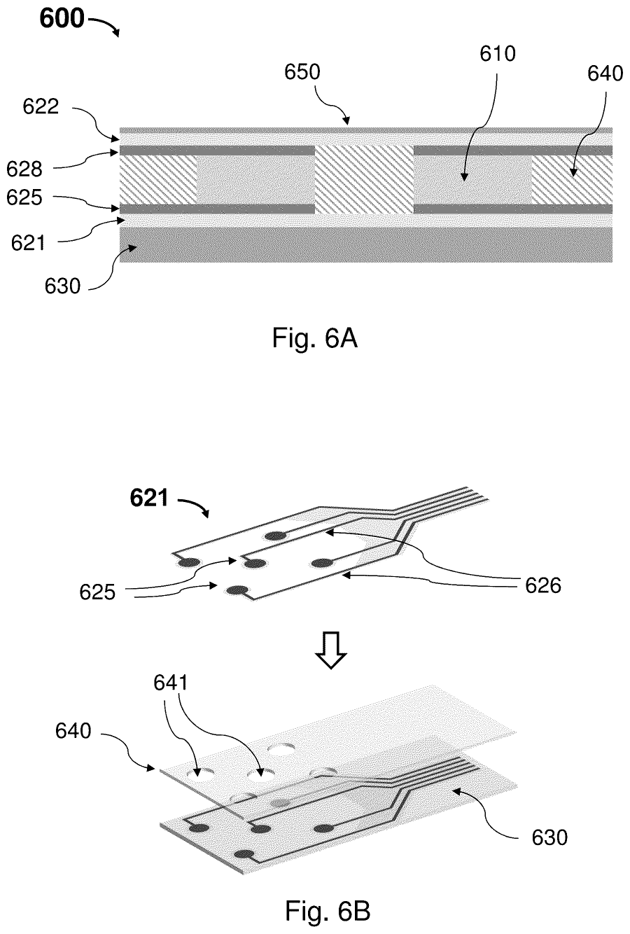

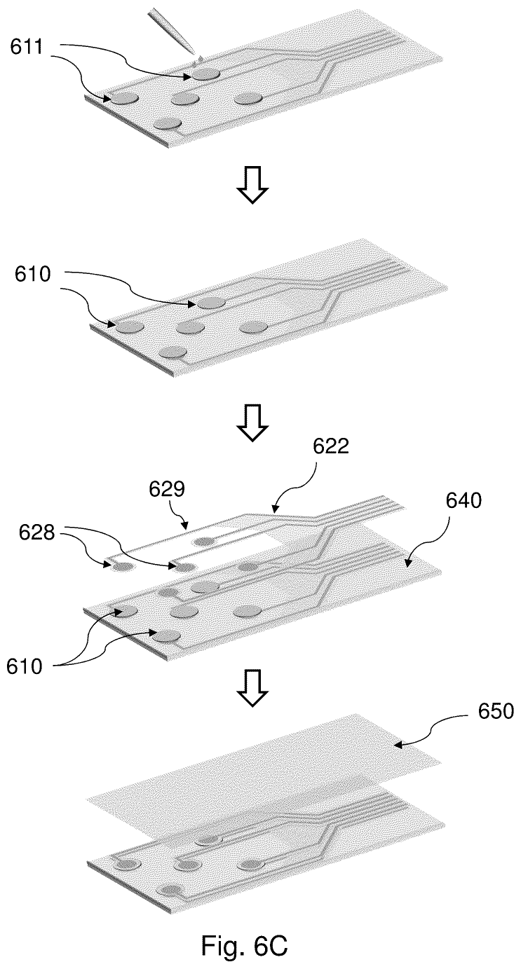

Now referring to FIG. 6A, a cross-sectional view of an example cross-plane flexible thermal sensor is shown. In this example, a flexible thermal sensor 600 contains a first flexible printed circuit board (FPCB) 621 attached on a flexible substrate 630, mask layer 640 (which contains a receiving portion with five separate spaces), PQ based ionic hydrogel 610 (in five separate areas defined by the remaining spaces of the receiving portion of the mask layer), and a second flexible printed circuit board (FPCB) 622 disposed on the first flexible printed circuit board (FPCB) 621 indirectly (i.e., over the PQ based ionic hydrogel 610 and at least a portion of the mask layer 640) and an insulating layer 650 over the second flexible printed circuit board (FPCB) 622. In other words, the PQ based ionic hydrogel 610 and at least a portion of the mask layer 640 are sandwiched between the first flexible printed circuit board (FPCB) 621 and the second flexible printed circuit board (FPCB) 622. The first flexible printed circuit board (FPCB) 621 contains a plurality of (five) first electrodes 625, first connecting lines and the individual first electrode is in electrical communication with the individual first connecting line. The second flexible printed circuit board (FPCB) 622 is structurally similar to the first flexible printed circuit board (FPCB) 621 and contains the same number of second electrodes 628, each juxtapose to the respective first electrode. In this example, the plurality of first electrodes 625 and the corresponding plurality of second electrodes 628 are individually contacted and connected by the PQ based ionic hydrogel 610, resulting in the individual first electrodes 625 and the corresponding individual second electrodes 628 being in electrical communication with each other by the PQ based ionic hydrogel 610.

With the first electrodes 625 and the second electrodes 628 attached to the bottom and top surfaces of the PQ based ionic hydrogels 610, the temperature difference in the cross-plane direction will generate a potential difference between the first electrodes 625 and the second electrodes 628, and thus convert the temperature information to an electrical signal cross the plane.

In some examples, the plurality of the first electrodes 625 of the first flexible printed circuit board (FPCB) 621 are the reference electrodes, while the plurality of the second electrodes 628 of the second flexible printed circuit board (FPCB) 622 are the sensing electrodes.

During operation, in some examples, the bottom surface of the flexible thermal sensor 600 will be in contact with (or further contains) a heat sink to stabilize the thermal condition, while the top surface perceives the external thermal stimulus.

Now referring to FIGS. 6B-6C, where an example fabrication method of the cross-plane flexible thermal sensor 600 is shown. A first flexible printed circuit board (FPCB) 621 contains a plurality of (e.g., five) electrodes 625 and a plurality of (e.g., five) connecting lines 626 with a designed pattern as shown in FIG. 6B. As shown in FIG. 6B, the first flexible printed circuit board (FPCB) 621 is prepared and placed on a flexible substrate 630 (e.g., PI, Polydimethylsiloxane (PDMS), Ecoflex, rubber, etc.). Then, a flexible mask layer 640 (e.g., PI tape, 3M VHB tape, etc.) with receiving portion 641 of the designed pattern is aligned with the first flexible printed circuit board (FPCB) 621 and disposed onto the first flexible printed circuit board (FPCB) 621. In this example, the receiving portion 641 contains five separate spaces sized and shaped to correspond to the first and second electrodes. In some examples, the receiving portion 641 of the mask layer 640 is fabricated through laser cutting, punching or 3D printing. The receiving portion 641 defines at least one space that is sized and shaped large enough to receive at least one electrode 625 and to form at least one remaining space in the receiving portion for receiving a mixture (ionic hydrogel composition) 611 for the formation of the PQ based ionic hydrogel 610. Next, the mixture 611 (e.g., a homogeneous ionic solution of PQ-10/[EMIM]Cl) is drop casted onto the receiving portion 641, filling the spaces defined by the receiving portion 641 of the mask layer 640 (i.e., the exposed regions of the first flexible printed circuit board (FPCB) 621) as shown in FIG. 6C. Upon drying (e.g., in ambient environment), PQ based ionic hydrogel 610 is formed in the remaining spaces defined by the receiving portion 641 of the mask layer 640.

During the drying process, a second flexible printed circuit board (FPCB) 622 is aligned and attached onto the PQ based ionic hydrogel 610 and the mask layer 640 disposed on the first flexible printed circuit board (FPCB) 621. The second flexible printed circuit board (FPCB) 622 comprises a plurality of second electrodes 628 and a plurality of second connecting lines 629, and the individual second electrode 628 is in electrical communication with the individual second connecting line 629. Each of the plurality of second electrodes 628 is positioned juxtapose to the corresponding first electrode 625, such that electrical communication is established between each of the plurality of first electrodes 625 and the corresponding second electrode 628 through the PQ based ionic hydrogel 610. Finally, the top surface of the flexible thermal sensor 600 is covered by an insulating layer 650 for packaging.

The exemplary embodiments of the present invention are thus fully described. Although the description referred to particular embodiments, it will be clear to one skilled in the art that the present invention may be practiced with variation of these specific details. Hence this invention should not be construed as limited to the embodiments set forth herein.

Compositions, devices and methods discussed within different figures can be added to or exchanged with methods in other figures. Further, specific numerical data values (such as specific quantities, numbers, categories, etc.) or other specific information should be interpreted as illustrative for discussing example embodiments. Such specific information is not provided to limit example embodiment.

For example, in certain embodiments, a flexible thermal sensor comprises a first flexible printed circuit board (FPCB), but different types, other numbers (e.g., two, three, four, five, six, seven, eight, nine, ten or more), sizes (e.g. oversized), shapes (oval, circular, or triangular) and configurations may be used, according to the practical need.

For example, flexible thermal sensors in the described examples are substantially flexible, but in other examples, only the sensing electrode portion and/or the common reference electrode portion of the flexible thermal sensor is substantially flexible and the rest of the flexible thermal sensor may be semi-flexible, stretchable, semi-stretchable, non-stretchable rigid, or solid, and may be made on different substrates such as polyimide (PI), polyethylene (PE), polytetrafluoroethylene (PTFE), polyvinylidene chloride (PVDC), polydimethylsiloxane (PDMS), silicone (such as Ecoflex), rubber, acrylic (such as Very High Bond (VHB)), metal, or combination thereof.

For example, in certain embodiments, components of a flexible thermal sensor (i.e., flexible substrate, FPCB, mask layer, PQ based ionic hydrogel, insulating layer) are individually disposed on one another, but other reversible or irreversible attachment means amongst the components of a flexible thermal sensor may be used, such as adhesion, clip, hook, chemically bonding or soldering.

For example, in some embodiments, polyquaternium-10 (or PQ-10) is used as the polymer matrix. In some other embodiments, polyquaternium-10 or PQ-10 can be replaced by other polyquaterniums with quaternary ammonium groups such as polyquaternium-1, polyquaternium-7, polyquaternium-22 and/or combination thereof.

For example, in some embodiments, water is used as a solvent for the hydrogel, but other solvents such as ionic liquids, ethanol, ethylene glycol, dimethyl sulfoxide, or combination thereof may be used.

For example, in some embodiments, polyquaterniums such as PQ-10 are provided in the form of powders. In some embodiments, polyquaterniums can be provided in the form of crystals, granules, semi-solids, gels, or liquids if appropriate.

For example, in some embodiments, the example methods are described in sequential order, but certain steps can be in different orders if appropriate.

For example, in some embodiments, the configurations of the first and/or second FPCB are customized as shown in the figures, but they can be configured into different patterns, shapes and sizes as required. In some examples, five electrodes are provided, but different numbers and different relative configurations/positions of the first and/or second electrodes and the first and/or second connecting lines can be provided according to the practical need.

For example, in some embodiments, the ionic hydrogels are prepared from the hydrogel compositions by drying, but other methods may be used instead, such as adding agents for crosslinking etc.

What is claimed is:

1. A thermometric hydrogel composition for thermal sensor, comprising:
a) at least one polyquaternium (PQ) comprising at least one quaternary ammonium group;
b) at least one ion source; and
c) a solvent.

2. The composition of claim 1, wherein the at least one ion source comprises one or more acids, alkalis, salts, ionic liquids, and/or combination thereof.

3. The composition of claim 1, wherein the solvent is water, ionic liquids, ethanol, ethylene glycol, dimethyl sulfoxide, or combination thereof.

4. The composition of claim 1, wherein the composition is dried to a water content of about 14-55 wt. % to form a PQ based ionic hydrogel, wherein final PQ and ion source contents are in the ranges of 15-72 wt. % and 7-58 wt. %, respectively.

5. The composition of claim 1, wherein the at least one ion source is sodium hydroxide (NaOH) and the weight ratio of PQ:NaOH is about 5:1 to 5:8.

6. The composition of claim 5, wherein
the PQ is polyquaternium-10 (PQ-10) which is about 3-4% by weight; and
the NaOH is about 0.6-4.9% by weight of the composition,
wherein the composition has a pH value of about 13-14.

7. The composition of claim 1, wherein the at least one ion source is 1-ethyl-3-methylimidazolium chloride ([EMIM]Cl) and the weight ratio of PQ:[EMIM]Cl is about 1:0.5 to 1:2.

8. The composition of claim 7, wherein
the PQ is PQ-10 which is about 7.7-8.7% by weight; and
the [EMIM]Cl is about 4.3-15.4% by weight of the composition,
wherein the composition has a pH value of about 4-11.

9. A method of preparing a thermometric hydrogel composition for thermal sensor, comprising the step of:
a. mixing at least one polyquaternium (PQ) into a solution comprising at least one ion source to form a mixture;
b. adjusting the pH value of the mixture to form a composition;
c. drying the composition to a gel state, such that a PQ based ionic hydrogel is formed.

10. The method of claim 9, wherein the at least one ion source comprises one or more acids, alkalis, salts, ionic liquids, and/or combination thereof.

11. The method of claim 9, wherein the at least one ion source is NaOH and the weight ratio of PQ:NaOH is about 5:1 to 5:8.

12. The method of claim 11, wherein the composition comprises:
the PQ is PQ-10 of about 3-4% by weight; and
the NaOH of about 0.6-4.9% by weight of the composition,
wherein the pH value is adjusted to about 13-14.

13. The method of claim 9, wherein the step c) drying the composition to gel state is performed at about 40° C. for 20-50 hours, until the water content is about in the range of 14-55 wt. %.

14. The method of claim 9, wherein the at least one ion source is [EMIM]Cl and the weight ratio of PQ:[EMIM]Cl is about 1:0.5 to 1:2.

15. The method of claim 14, wherein the composition comprises:
the PQ is PQ-10 of about 7.7-8.7% by weight; and
the [EMIM]Cl of about 4.3-15.4% by weight of the composition,
wherein the pH value is adjusted to about 4-11.

16. A flexible thermal sensor, comprising:
a. a flexible substrate;
b. a first flexible printed circuit board (FPCB) that is disposed on the flexible substrate, the first FPCB comprising:
i. a plurality of first electrodes; and
ii. a plurality of first connecting lines,
wherein the individual first electrode is in electrical communication with the individual first connecting line;
c. a mask layer that is disposed on the first FPCB;
d. at least one PQ based ionic hydrogel; and
e. an insulating layer that is disposed onto the first FPCB,
wherein the mask layer comprises at least one receiving portion, defining at least one space that is sized and shaped large enough to receive at least a portion of the first electrodes and at least one remaining space to receive the at least one PQ based ionic hydrogel, such that at least a portion of the first electrodes is in electrical communication with the at least one PQ based ionic hydrogel.

17. The sensor of claim 16, wherein the mask layer comprises one receiving portion, defining one space sized and shaped large enough to receive the plurality of first electrodes, and the remaining space is sized and shaped large enough to receive one PQ based ionic hydrogel to at least cover the plurality of first electrodes, such that the plurality of first electrodes are in electrical communication with each other through the PQ based ionic hydrogel.

18. The sensor of claim 16, further comprising a second flexible printed circuit board (FPCB), the second FPCB comprising:
a plurality of second electrodes; and
a plurality of second connecting lines,
wherein the individual second electrode is in electrical communication with the individual second connecting line,
wherein each of the plurality of second electrodes is positioned juxtapose to the corresponding first electrode,
wherein the second FPCB is disposed on the first FPCB and below the insulating layer, and
wherein the mask layer comprises a plurality of receiving portions, defining a plurality of spaces, individual space is sized and shaped large enough to receive individual first electrode and individual second electrode, and the remaining space between the first electrode and the second electrode is sized and shaped large enough to receive PQ based ionic hydrogel therebetween, such that the first electrode is in electrical communication with the second electrode through the PQ based ionic hydrogel.

19. The sensor of claim 16, wherein at least one electrode is a sensing electrode and at least another one electrode is a reference electrode.

20. The sensor of claim 16, wherein the PQ based ionic hydrogel comprises a composition as claimed in claim 1.

21. The sensor of claim 16, wherein the PQ based ionic hydrogel is prepared by a method as claimed in claim 9.

22. A method of making a flexible thermal sensor, comprising:
a. providing a first flexible printed circuit board (FPCB) onto a flexible substrate, wherein the first FPCB comprises a plurality of first electrodes and a plurality of first connecting lines, wherein the individual first electrode is in electrical communication with the individual first connecting line;
b. attaching at least one mask layer onto the first FPCB, wherein the mask layer comprises at least one receiving portion, defining at least one space that is sized and shaped large enough to receive at least a portion of the first electrodes and at least one remaining space to receive at least one PQ based ionic hydrogel;
c. casting a thermometric hydrogel composition comprising at least one dissolved PQ and at least one ion source onto the at least one remaining space;
d. drying the composition to a gel state to form the at least one PQ based ionic hydrogel, such that at least a portion of the first electrodes is in electrical communication with the at least one PQ based ionic hydrogel;
e. attaching an insulating layer onto the first FPCB.

23. The method of claim 22, further comprising a step of attaching a second flexible printed circuit board (FPCB) onto the first FPCB and below the insulating layer, prior to step (e), wherein the second FPCB comprises a plurality of second electrodes and
a plurality of second connecting lines, wherein the individual second electrode is in electrical communication with the individual second connecting lines, wherein each of the plurality of second electrodes is positioned juxtapose to the corresponding first electrode, and
wherein the mask layer comprises a plurality of receiving portions, defining a plurality of spaces, individual space is sized and shaped large enough to receive individual first electrode and individual second electrode, and the remaining space between the first electrode and the second electrode is sized and shaped large enough to receive PQ based ionic hydrogel therebetween, such that the first electrode is in electrical communication with the second electrode through the PQ based ionic hydrogel.

24. The method of claim 22, wherein at least one electrode is a sensing electrode and at least another one electrode is a reference electrode.

25. The method of claim 22, wherein the PQ based ionic hydrogel comprises a composition as claimed in claim 1.

26. The method of claim 22, wherein the PQ based ionic hydrogel is prepared by the method as claimed in claim 9.
